(19) United States
(12) Patent Application Publication
(10) Pub. No.: US 2011/0132255 A1
(43) Pub. Date: Jun. 9, 2011

(54) METHOD FOR PRODUCING EPITAXIAL SILICON WAFER

(75) Inventors: Hideaki KINBARA, Tokyo (JP); Naoyuki WADA, Tokyo (JP); Toshihiro OHUCHI, Tokyo (JP); Shinichi OGATA, Tokyo (JP); Hironori NISHIMURA, Tokyo (JP)

(73) Assignee: SUMCO CORPORATION, Tokyo (JP)

(21) Appl. No.: 12/887,815

(22) Filed: Sep. 22, 2010

(30) Foreign Application Priority Data
Sep. 25, 2009 (JP) 2009-221481

(51) Int. Cl. C30B 25/02; C30B 23/02

(52) U.S. Cl. 117/106; 117/84

(57) ABSTRACT

Since vapor-phase growth of an epitaxial film is performed on the surface of a mirror surface silicon wafer which is not subjected to final polishing, and the surface of the epitaxial film is thereafter subjected to HCl gas etching, the mirror polishing step is simplified, and the productivity is improved, that enables a reduction in cost, and it is possible to suppress the surface roughness of the epitaxial film as well.

### BACKGROUND OF THE INVENTION

1. Field of the Invention

The present invention relates to a method for producing an epitaxial silicon wafer, and in detail, to a method for producing an epitaxial silicon wafer in which vapor-phase growth of an epitaxial film is performed on the mirror-polished surface of a silicon wafer.

2. Description of the Related Art

For example, epitaxial silicon wafers have been known as substrates for manufacturing MOS devices. The epitaxial silicon wafer is configured such that vapor-phase growth of a p-type epitaxial film with a thickness of several μm, which is composed of single crystal silicon, is performed on a p-type and low-resistant (approximately 0.01 Ω·cm) silicon wafer having the mirror-finished surface.

Silicon wafers having the mirror-finished surfaces are produced such that a single crystal silicon ingot grown by the CZ (Czochralski) process is sliced, and the obtained silicon wafer is subjected to beveling, lapping (grinding process), and etching sequentially, and the wafer surface is thereafter subjected to mirror polishing.

In a general mirror polishing method, the surface of a silicon wafer is subjected to primary mirror polishing, secondary mirror polishing, final mirror polishing, and cleaning after the respective polishing stages sequentially. The wafer surface is subjected to polishing processing at various stages such that its abrasive grains become finer at every transition of the stage of mirror polishing, and its polishing cloth is decreased in degree of hardness, to make the plane roughness of the wafer surface be a lower value.

Meanwhile, in such a precise mirror polishing method at many stages, polishing and cleaning are repeated at the respective stages, which leads to a longer polishing time for a low-resistant wafer having a higher degree of hardness. As a result, the surface of the silicon wafer deteriorates in flatness, that generates pits in the wafer surface and brings about shear droop or periodic unevenness on the outer circumference of the silicon wafer, and this causes deterioration in flatness of the surface of the epitaxial film. Further, there is the problem of an increase in cost by multistage polishing processing, such as primary mirror polishing, secondary mirror polishing, and final mirror polishing, onto a silicon wafer.

Then, as a conventional technology to solve the problem, for example, Patent Document 1 has been known. This is the technology in which the surface of a silicon wafer after etching is subjected to only primary mirror polishing by use of a polishing liquid such as colloidal silica containing free abrasive grains, vapor-phase growth of an epitaxial film is performed on the polished surface. In this case, the roughness of the primary mirror-polished surface is an RMS value (Root Mean Square) of 0.3 nm or more and 1.2 nm or less when measuring a measuring area region of 1 μm×1 μm by utilizing an atomic force microscope.
[Patent Document 1] Japanese Published Examined Patent Application No. 3120825

However, the polishing liquid used for the primary mirror polishing in Patent Document 1 contains free abrasive grains. Therefore, the surface roughness is an RMS value of 0.3 nm or more when measuring a measuring area region of 1 μm×1 μm by an atomic force microscope. Further, in the case where an epitaxial film is formed on the wafer surface, the effect of the surface roughness of the silicon wafer prominently remains even after performing vapor-phase growth of the epitaxial film, which increases the surface roughness of the epitaxial film. In recent years, it is required to strictly control the sizes and numbers of LPD (Light Point Defects) observed on the surface of an epitaxial silicon wafer, and it is necessary to improve a roughness precision of the surface of the epitaxial silicon wafer in order to assure the presence or absence of LPD of minute sizes.

In addition, when the wafer surface is subjected to primary mirror polishing by use of a polishing liquid containing abrasive grains, there are many occurrences of process damage with a depth of about 5 nm or more in the wafer surface layer by mechanical actions in mirror polishing, which brings about another problem that the gate oxide integrity characteristics deteriorate. Further, when an epitaxial film is formed on such a wafer surface, the LPD density of the surface of the epitaxial film as well is increased. Moreover, aggregation of abrasive grains in a polishing liquid causes defects such as micro scratches caused by processes on the primary mirror polished surface of the silicon wafer. As a result, an amount of generating LPD is increased. In detail, 1000 or more LPDs of 130 nm or more in size have emerged per silicon wafer with a diameter of 300 mm.

### BRIEF SUMMARY OF THE INVENTION

Thus, as a result of intensive research, the inventors have found that vapor-phase growth of an epitaxial film is performed on the surface of a silicon wafer which is not subjected to final polishing, and the surface of the epitaxial film is thereafter subjected to etching with an HCl (hydrochloric acid) gas, which may provide an epitaxial silicon wafer in which the surface roughness of the epitaxial film is decreased at low cost, and has thus accomplished the present invention.

Further, as a result of intensive research, the inventors have found that, when the surface of a silicon wafer is subjected to mirror polishing by use of a polishing liquid of alkaline solution which is free of abrasive grains, and to which a water-soluble polymer is added, and vapor-phase growth of an epitaxial film is thereafter performed on the wafer surface, all the problems of LPD caused by free abrasive grains in the polishing liquid are solved, and has thus accomplished the present invention.

That is, an object of the present invention is to provide a method for producing an epitaxial silicon wafer in which, when it is possible to produce an epitaxial silicon wafer even by omitting final mirror polishing, productivity is improved by simplifying the mirror polishing step, which enables a reduction in cost, and additionally enables decrease in surface roughness of the epitaxial film.

Further, an object of the present invention is to provide a method for producing an epitaxial silicon wafer in which it is possible to decrease surface roughness of the wafer surface by lowering the density of LPD due to a process which is generated on the surface of the mirror-polished silicon wafer.

An aspect of the present invention is a method for producing an epitaxial silicon wafer including the steps of

performing vapor-phase growth of an epitaxial film on a surface of a silicon wafer subjected to mirror polishing except for final mirror polishing, and

etching a surface of the epitaxial film with an HCl gas after the vapor-phase growth of the epitaxial film.

According to this aspect of the present invention, a silicon wafer subjected to mirror polishing except for final mirror polishing is prepared, and vapor-phase growth of an epitaxial film is performed on the wafer surface. In this way, since it is possible to produce an epitaxial silicon wafer even while omitting final mirror polishing, the mirror polishing step is simplified and the productivity is improved, that enables a reduction in cost.

However, since final mirror polishing is not performed, the surface roughness of the silicon wafer is increased, and the effect of the surface roughness of the silicon wafer noticeably remains even after the vapor-phase growth of the epitaxial film, that increases the surface roughness of the epitaxial film. Then, the surface of the epitaxial film is subjected to dry etching with an HCl gas. At this time, on the boundary layer formed on the wafer surface, the convex portions of the wafer surface are easily etched rather than the concave portions due to HCl diffused in the boundary layer or Cl-radical generated by thermal decomposition of the HCl. As a result, the concave portions of the surface of the epitaxial film are etched by priority, which makes it possible to reduce the surface roughness.

The reason why the HCl gas etching is adopted from among many existing etching (including cleaning) techniques is as follows. That is, the point that an HCl gas has a high etching rate with respect to silicon, and is capable of etching an entire surface of an epitaxial film for a short time therewith, and the point that an HCl gas is a semiconductor-grade and extremely high pure gas, which allows to obtain an epitaxial film which is excellent in surface roughness and with little impurity contamination, and the like may be cited. In addition, the point that it is possible to process an epitaxial silicon wafer continuously in the same device without another step after the growth of the epitaxial film, which makes it possible to construct a process suitable for mass production of epitaxial silicon wafers as well may be cited.

As the silicon wafer, for example, a single crystal silicon wafer, a polycrystalline silicon wafer, or the like may be adopted.

A diameter of the silicon wafer may be, for example, 100 mm, 125 mm, 150 mm, 200 mm, 300 mm, 450 mm, or the like.

With the current situation in the final mirror polishing step, the final mirror polishing step is performed so as to lower the plane roughness (roughness) of the surface of the silicon wafer to a level less than an RMS value of 0.1 nm when measuring a measuring area region of 10 μm×10 μm by an atomic force microscope. Therefore, for example, a suede-type polishing cloth for final mirror polishing with a degree of hardness (JIS-A) of 60 to 70, a compression rate of 3 to 7%, and a compressive elasticity modulus of 50 to 70% is used as a polishing cloth, and a polishing agent containing free abrasive grains whose mean grain diameter is 10 to 50 nm (silica or the like) is adopted. Further, mirror polishing processing in which, for example, polishing pressure is approximately 100 g/cm² and an amount of polishing is approximately 0.5 μm as polishing conditions, is adopted.

Meanwhile, as described above, there is a problem that costs for final mirror polishing processing for the silicon wafer are brought about, and additionally, there is a concern of causing defects such as micro scratches caused by processes by aggregation of free abrasive grains or the like. Therefore, it is effective that the final mirror polishing is omitted.

Further, as the mirror polishing except for final mirror polishing, as will be described later, it is desirable that the mirror polishing is performed with a polishing liquid in which a water-soluble polymer is added to an alkaline solution free of abrasive grains. In addition, it is desirable that plane roughness of the surface of the silicon wafer after the mirror polishing processing is less than or equal to an RMS value of 0.3 nm when measuring a measuring area region of 10 μm×10 μm by an atomic force microscope. Thereby, it is possible to obtain an epitaxial silicon wafer in which the roughness of the surface of the epitaxial film is remarkably reduced by a synergetic effect with HCl gas etching carried out after the epitaxial growth processing.

As a polishing cloth used for mirror polishing except for final mirror polishing, for example, an urethane-type polishing cloth with a degree of hardness (JIS-A) of 75 to 85 and a compression rate of 2 to 3% may be adopted. Further, as a material of the polishing cloth, expandable polyurethane, suede-type polyurethane, a nonwoven fabric made of polyester, or the like may be adopted.

As other mirror polishing conditions for the wafer surface except for final mirror polishing, for example, a polishing rate of 0.2 to 0.6 μm per minute, an amount of polishing of 5 to 20 μm, a polishing load of 200 to 300 g/cm², a polishing time of 10 to 90 minutes, a temperature of the polishing liquid in polishing of 20 to 30 degrees, and the like may be cited. Further, as a polishing liquid, any polishing liquid which contains free e abrasive grains and is free of free abrasive grains may be used. As a polishing liquid containing free abrasive grains, for example, a polishing liquid in which silica whose mean grain diameter is 50 to 200 nm or the like is diffused in various types of alkaline solutions (amine, KOH, NaOH, and the like) serving as main liquids may be used. As a polishing liquid free of free abrasive grains, a polishing liquid in which the various types of alkaline solutions are adopted as main liquids may be used.

For the mirror polishing for the silicon wafer, a single wafer polishing device may be used, or a batch-type polishing device that simultaneously polishes a plurality of silicon wafers may be used.

Further, the polishing for the silicon wafer may be one side polishing only for the surface or double side polishing for simultaneously polishing the surface and rear surface of the wafer. As a double side polishing device, a sun gear (planetary gear) system device, or a sun gearless system that causes the carrier plate to make a circular movement without rotating on its own axis to simultaneously polish both the surface and rear surface of the silicon wafer may be adopted. In particular, by use of a double side polishing device, it is possible to achieve high planarization of, not only the wafer surface, but also the wafer rear surface by one-time polishing processing, which is effective for providing a highly planarized epitaxial wafer at low cost.

Moreover, the wafer surface may be subjected to mirror polishing until the end under the same mirror polishing processing conditions. Further, mirror polishing in which the composition of the polishing liquid (medicinal solution) or the polishing conditions are modified may be carried out several times in the same polishing device. In the case where multistage mirror polishing is carried out, for example, the polishing is performed in the following method. That is, at an initial stage of mirror polishing, the wafer surface is polished at a high polishing rate by controlling the concentration of the medicinal solution such as an alkaline solution or a water-soluble polymer, or the number of rotations of the polishing surface plates so as to be capable of rapidly removing the process damage in the wafer surface layer introduced by slicing, a grinding process, or the like. Thereafter, the wafer surface is polished at a low polishing rate so as not to introduce new process damage into the wafer surface layer in mirror polishing by changing the respective surface polishing conditions.

The mirror-polished silicon wafer is subjected to cleaning processing before epitaxial growth processing in order to remove medicinal solution or particles attached to the wafer surface. As this cleaning processing, publicly-known repeated SCl cleaning, cleaning with a mixed solution of ozone and hydrofluoric acid, repeated cleaning in which ozone water cleaning and hydrofluoric acid solution cleaning are alternately applied may be adopted. Liquid types, concentrations, processing times of the respective cleaning liquids used at that time may be within the cleaning conditions under which it is possible to remove the surface of the silicon wafer by approximately 0.2 to 10 nm so as to be capable of removing particles without bringing about contamination onto an epitaxial film to be grown.

As a material of the epitaxial film, for example, single crystal silicon or the like may be adopted.

As a vapor-phase epitaxial deposition method for the epitaxial film, for example, an atmospheric pressure vapor-phase epitaxy, a low pressure vapor-phase epitaxy, a metal-organic-vapor-phase epitaxy, or the like may be adopted. In the vapor-phase epitaxy, for example, a susceptor which is circular in plan view in which silicon wafers are accommodated in a transversely mounted state (a state where the surface and rear surface are horizontal) in one or a plurality of wafer accommodating portions may be used. The vapor-phase epitaxy may be homoepitaxy for performing epitaxial growth of a material which is the same as that of a wafer, or heteroepitaxy for performing epitaxial growth of a material different from that of the wafer. In addition, the thinner the thickness of the epitaxial film is, the more the property of the epitaxial film receives the effect of the property of the wafer surface, and therefore, it is desirable that an epitaxial film with a thickness of 1 to 10 μm is formed.

The HCl gas is diluted by a carrier gas for use. As a carrier gas, for example, a hydrogen gas, an argon gas, or the like may be adopted.

An amount of etching on the surface of the epitaxial film with the HCl gas is 10 to 1000 nm. When an amount of etching is less than 10 nm, it is impossible to sufficiently improve the surface roughness of the epitaxial film. Further, when an amount of etching is more than 1000 nm, an etching processing time with the HCl gas is increased, which deteriorates the productivity. It is particularly preferable that an amount of etching on the surface of the epitaxial film with the HCl gas is 10 to 100 nm. Within this range, it is possible to securely improve the surface roughness of the epitaxial film within a range of 1 to 10 μm, and it is possible to prevent the productivity from deteriorating by excessive etching with the HCl gas.

Other conditions for gas etching for the surface of the epitaxial film by use of the HCl gas (HCl gas etching) are arbitrary.

Such HCl gas etching may be carried out immediately after deposition of the epitaxial film in a reacting furnace of the epitaxial growth apparatus. In this case, a dedicated dry etching device is not necessary, and it does not take much time for transmission of an epitaxial silicon wafer between both devices. It is a matter of course that there is no problem in quality of the surface of the epitaxial film even by utilizing a dedicated dry etching device.

Further, in the present invention, it is desirable that a silicon wafer polished with a polishing liquid in which a water-soluble polymer is added to an alkaline solution free of abrasive grains is used as the silicon wafer.

In this way, when the surface of the silicon wafer immediately before deposition of the epitaxial film is subjected to mirror polishing by use of the polishing liquid composed of alkaline solution free of abrasive grains, the wafer surface in mirror polishing is mirror-polished by a chemical action repeating oxidization etching and peeling of oxides. As a result, it is possible to avoid process damage by a mechanical action brought about in the case of mirror polishing by use of abrasive grains, which provides a wafer excellent in gate oxide integrity characteristics. In addition, because of the polishing which does not use abrasive grains, it is possible to considerably reduce the generation of defects such as micro scratches caused by processes by aggregation of abrasive grains or the like, and it is possible to lower the density of LPD generated on the surface of the epitaxial film formed thereafter.

Further, since the water-soluble polymer is added to an alkaline solution free of abrasive grains, the water-soluble polymer receives some of the polishing load in polishing, which makes it possible to lower its frictional coefficient. As a result, it is possible to lower the surface roughness to less than or equal to an RMS value of 0.3 nm not only in a small measuring area region of 1 μm×1 μm, but also for an RMS value in a large measuring area region of 10 μm×10 μm by use of an atomic force microscope, and it is possible to produce an epitaxial silicon wafer having an epitaxial film excellent in quality of the surface roughness.

Moreover, the water-soluble polymer added to the alkaline solution forms a low friction coating between the polishing pads and the carrier plate, which efficiently lowers the frictional coefficient. Therefore, an elastic deformation in the carrier plate is suppressed, which makes it possible to reduce noise generated from the carrier plate. Moreover, since abrasive grains are not used, it is possible to lower the concern that the outer circumference of the wafer is excessively polished due to abrasive grains in the mirror polishing liquid getting dense at the outer circumference of the silicon wafer, which may bring about outer circumferential shear droop.

It is preferable that, an alkaline solution adjusted to be within a range of pH8 to pH14 is used as the alkaline solution. When the alkaline solution is lower than pH8, its etching effect is too low, which may easily bring about defects such as scratches or scars caused by processes on the surface of the silicon wafer. Further, when the alkaline solution is higher than pH14 as a strong basic solution, it is difficult to handle the polishing solution. As an alkaline agent (pH adjuster), an ammonia solution, an alkali hydroxide solution of potassium hydrate or sodium hydrate, or an alkaline carbonate solution may be adopted. In addition, a hydrazine or amine solution may be adopted. It is particularly desirable that amine is used from the standpoint of raising a polishing rate.

It is desirable that, hydroxyethyl cellulose or polyethylene glycol may be used as the water-soluble polymer added to the alkaline solution. In particular, since it is possible to relatively easily obtain highly pure hydroxyethyl cellulose, which is of higher molecular weight, the hydroxyethyl cellulose is capable of forming a low friction coating between the polishing pads and the carrier plate, which makes it possible to efficiently lower the frictional coefficient.

Further, it is desirable that a concentration of the water-soluble polymer added to the alkaline solution is adjusted to be within a range of 0.01 ppm to 1000 ppm. When a concentration of the water-soluble polymer is lower than 0.01 ppm, friction in polishing is too high, which may bring about defects caused by processes on the mirror-polished wafer surface. Further, when a concentration of the water-soluble polymer is higher than 1000 ppm, its polishing rate is remarkably lowered, which results in time-consuming mirror polishing step.

Generally, there is a natural oxide film which is 5 to 20 Å in thickness on the surface of the silicon wafer before mirror polishing, and therefore, it is difficult to remove the natural oxide film by only chemical polishing using only the alkaline solution free of abrasive grains. Therefore, it is desirable that the natural oxide film on the surface of the silicon wafer is removed by oxidization etching or the like in advance of mirror polishing. Or, it is desirable that, after primary mirror polishing using abrasive grains is carried out to remove the natural oxide film on the surface of the silicon wafer, the surface of the silicon wafer is subjected to mirror polishing as secondary polishing processing with a polishing liquid in which a water-soluble polymer is added to an alkaline solution free of abrasive grains.

Further, in the present invention, it is desirable that mirror polishing is performed such that plane roughness of the surface of the silicon wafer is less than or equal to an RMS value of 0.3 nm when measuring a measuring area region of 10 μm×10 μm by an atomic force microscope.

Thereby, it is possible to enhance the quality of the surface roughness of an epitaxial film to be formed thereafter. In the case where the plane roughness of the wafer surface is greater than 0.3 nm, the surface roughness of the grown epitaxial film is made too high. Therefore, even when the surface of the grown epitaxial film is etched with an HCl gas, it is difficult to provide an epitaxial silicon wafer having an epitaxial film excellent in quality of the surface roughness. For example, a false detection is easily caused in the case where minute LPD of 50 nm or 60 nm in size are tested by use of a surface tester (SP-2: manufactured by KLA-Tencor Corporation), which makes it difficult to assure the epitaxial silicon wafers as products.

Moreover, in the present invention, it is desirable that a thickness of the epitaxial film is formed to be 1 to 10 μm.

When a thickness of the epitaxial film is formed to be 1 to 10 μm, the surface roughness of the epitaxial film is improved. That is, when a film thickness of the epitaxial film is less than 1 μm, the epitaxial film is too thin, the shape of the roughness (unevenness) of the wafer surface is directly passed to the surface of the epitaxial film, which deteriorates the surface roughness of the epitaxial film. The thicker the epitaxial film is formed, the lower the effect of the roughness of the wafer surface is suppressed. Meanwhile, when a thickness of the epitaxial film is more than 10 μm, epitaxial growth processing for a long time is necessary and the productivity deteriorates, which results in a sharp gain in manufacturing costs. Provided that a film thickness of the epitaxial film is formed to be 1 to 10 μm, it is possible to stably produce epitaxial silicon wafers excellent in surface quality whose surface roughness is suppressed at low cost.

Further, in the present invention, it is desirable that, as conditions of etching for the surface of the epitaxial film with the HCl gas, an HCl gas concentration in an atmosphere gas composed of a mixed gas of an HCl gas and a carrier gas is 0.3 to 3.0% (by volume), a heating temperature for the silicon wafer is 1000 to 1180 degrees, and an etching time is 0.3 to 5.0 minutes. Thereby, it is possible to obtain an amount of etching with the HCl gas necessary for improvement in roughness without deterioration in productivity.

When an HCl gas concentration is lower than 0.3% (by volume), an excessive amount of time is taken for obtaining an amount of HCl gas etching necessary for improvement in roughness, that deteriorates the productivity. Further, when an HCl gas concentration is higher than 3.0%, the performance of HCl gas etching becomes excessive. Therefore, a by-product material in the furnace produced in the process of epitaxial growth is peeled off, which results in an increase in LPD generated due to the peeled by-product material being attached to the wafer. It is specifically preferable that an HCl gas concentration is 0.6 to 1.5%. Within this range, it is possible to maintain the performance of HCl gas etching in an appropriate state, which makes it possible to perform HCl gas etching without deterioration in productivity. In addition, since an excessive Cl-radical is not reacted to members in the furnace, it is possible to prevent metal contamination onto the wafer, and also to peel off the by-product material in the furnace, to prevent LPD from being generated.

When a heating temperature for the silicon wafer (epitaxial silicon wafer) is lower than 1000 degrees, it is impossible to obtain the necessary performance of HCl gas etching. Further, when a heating temperature for the silicon wafer is higher than 1180 degrees, the silicon wafer is exposed to a high temperature, to generate distortion or slippage. It is preferable that a heating temperature for the silicon wafer is 1050 to 1150 degrees. Within this range, it is possible to shorten a time for varying a temperature from an epitaxial growth temperature to an HCl gas etching temperature to be stable, which makes it possible to perform epitaxial growth without deterioration in productivity.

When an etching time for the surface of an epitaxial film is shorter than 0.3 minutes, it is impossible to obtain an amount of HCl gas etching necessary for improvement in roughness. Further, when an etching time for the surface of an epitaxial film is longer than 5 minutes, the productivity of the epitaxial silicon wafers deteriorates. It is preferable that an etching time for the surface of an epitaxial film is 0.3 to 3.0 minutes. Within this range, it is possible to obtain an amount of HCl gas etching sufficient for improvement in roughness, and prevent the productivity of epitaxial silicon wafers from deteriorating.

### BRIEF DESCRIPTION OF THE SEVERAL VIEWS OF THE DRAWINGS

FIG. 1 is a flow sheet of a method for producing an epitaxial silicon wafer of an example 1 according to the present invention.

FIG. 2 is a perspective view of a sun-gearless system double side polishing device which is used in the method for producing the epitaxial silicon wafer of the example 1 according to the present invention.

FIG. 3 is a cross sectional view of major parts of the sun-gearless system double side polishing device which is used in the method for producing the epitaxial silicon wafer of the example 1 according to the present invention.

FIG. 4 is an enlarged cross sectional view of major parts of a vapor phase epitaxial growth apparatus used in the method for producing the epitaxial silicon wafer of the example 1 according to the present invention.

FIG. 5A is a three-dimensional graph showing the plane roughness when observing a measuring area region of 10 μm×10 μm of the surface of the epitaxial film before HCl gas etching by an atomic force microscope.

FIG. 5B is a three-dimensional graph showing the plane roughness when observing a measuring area region of 10 μm×10 μm of the surface of the epitaxial film after HCl gas etching by an atomic force microscope.

### DETAILED DESCRIPTION OF THE INVENTION

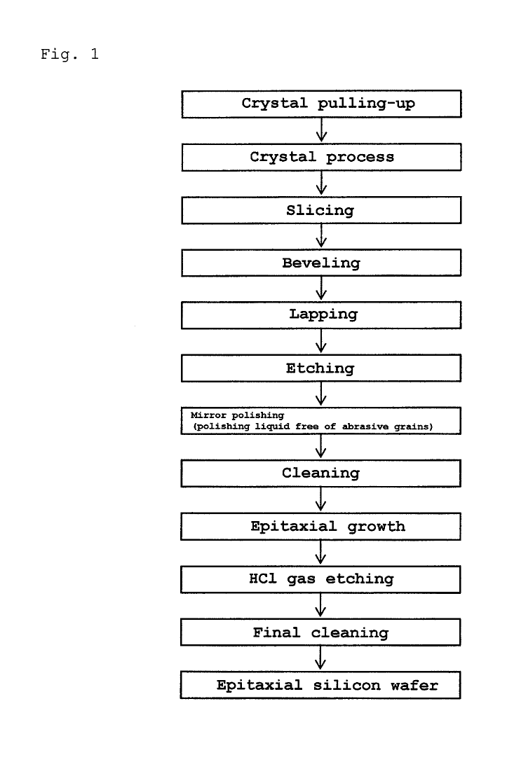

Hereinafter, a method for producing an epitaxial silicon wafer according to an example 1 of the present invention will be described with reference to the flow sheet of FIG. 1. Here, a method for producing an epitaxial silicon wafer for manufacturing a bipolar IC device will be described as an example.

That is, the method for producing the epitaxial silicon wafer according to the example 1 includes a crystal pulling-up step, a crystal process step, a slicing step, a beveling step, a lapping step, an etching step, a mirror polishing step, a cleaning step, an epitaxial growth step, an HCl gas etching step, and a final cleaning step.

Hereinafter, the respective steps will be described in detail.

In the crystal pulling-up step, a single crystal silicon ingot which is 306 mm in diameter, 2500 mm in length of its straight body section, 0.01 Ω·cm in specific resistance, and 1.0×10¹⁸ atoms/cm³ in initial oxygen concentration is pulled up by the Czochralski process from a silicon melt to which boron is doped at a predetermined amount inside a crucible.

Next, in the crystal process step, the one single crystal silicon ingot is sliced into a plurality of crystal blocks, and subsequently, outer circumferential grinding of each of the crystal blocks is performed. In detail, the outer circumference of the crystal block is outer-circumferentially grinded by 6 mm by an outer circumferential grinding device having a resinoid grind stone containing abrasive grains (SiC) of #200, thereby, forming each of the crystal blocks into a cylindrical form.

In the slicing step, a wire saw in which a wire is wound around three grooved rollers arranged in a triangular shape is used. The wire saw slices the silicon single crystal into many silicon wafers which are 300 mm in diameter and 775 μm in thickness.

In the following beveling step, a rotating beveling grind stone is pressed against an outer circumference of the silicon wafer to effect beveling.

In the lapping step, a double side lapping device is used to lap the surface and rear surface of the silicon wafer simultaneously. More specifically, the surface and rear surface of the silicon wafer are lapped between the upper and the lower surface plates rotating at a predetermined speed.

In the etching step, the silicon wafer after lapping is immersed into an acid etching solution in an etching tank to effect etching, thereby removing damage resulting from the beveling and the lapping, and a natural oxide film on the surface of the silicon wafer. When mirror polishing is performed with a polishing liquid free of abrasive grains in a state where a natural oxide film is formed on the surface of the silicon wafer, a process rate at an early stage of polishing is lowered. Then, it is effective to remove the oxide film on the surface of the silicon wafer in advance by etching. Meanwhile, in the case where a polishing liquid containing abrasive grains is used, this step is not necessary.

In the mirror polishing step, a sun-gearless system double side polishing device is used to mirror-polish the surface and rear surface (both sides) of the silicon wafer simultaneously by use of a polishing liquid in which a water-soluble polymer is added to an alkaline solution free of abrasive grains.

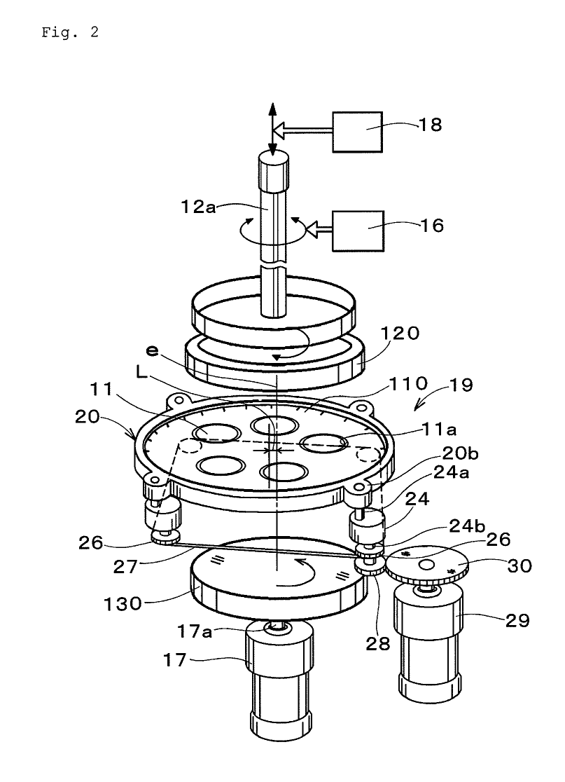

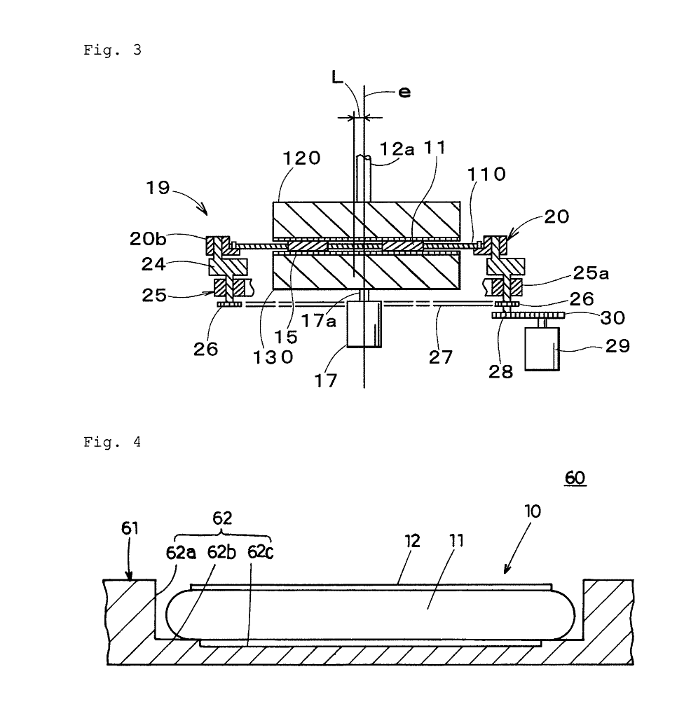

Hereinafter, the sun-gearless system double side polishing device will be described in detail with reference to FIGS. 2 and 3.

As shown in FIGS. 2 and 3, an upper surface plate 120 of the double side polishing device is driven to rotate in the horizontal plane via a rotating shaft 12a extending upward by an upper rotating motor 16. Further, the upper surface plate 120 is caused to vertically move up and down by an elevating device 18 moving back and forth axially. The elevating device 18 is used when the silicon wafer 11 is fed to and discharged from a carrier plate 110. In addition, the surface and rear surface of the silicon wafer 11 by the upper surface plate 120 and a lower surface plate 130 are pressed by pressure means such as airbag system means (not illustrated) built into the upper surface plate 120 and the lower surface plate 130. The lower surface plate 130 is rotated in the horizontal plane via an output shaft 17a thereof by a lower rotating motor 17. The carrier plate 110 makes a circular movement in a plane (horizontal plane) parallel to the surface of the plate 110 by a carrier circular movement mechanism 19 so that the plate 110 itself will not rotate on its own axis.

The carrier circular movement mechanism 19 is provided with an annular carrier holder 20 for holding a carrier plate 110 from the outside. The carrier circular movement mechanism 19 is connected to the carrier holder 20 via a connecting structure.

Four bearing units 20b protruding outward at every 90 degrees are placed on an outer circumference of the carrier holder 20. An eccentric shaft 24a installed in a protruding manner at an eccentric position of the upper surface of an eccentric arm 24 formed in a small diameter circular disk shape is inserted into holes formed to penetrate the central portion between the upper and lower surfaces of each of the bearing units 20b so that the eccentric shaft 24a is freely rotatable in the shaft holes. Further, a rotating shaft 24b is installed vertically at the central portion of the lower surface of each of these four eccentric arms 24. The respective rotating shafts 24b are inserted to be mounted into four bearing units 25a which are placed circumferentially at every 90 degrees on a ring-shaped device base 25, with the respective leading ends protruding downward. Sprockets 26 are firmly fixed to the respective leading ends of the rotating shafts 24b protruding downward. A timing chain 27 is bridged over on the respective sprockets 26 as a single string in a horizontal state. These four sprockets 26 and the timing chain 27 cause the four rotating shafts 24b to rotate simultaneously so that the four eccentric arms 24 make circular movement synchronously.

One of the four rotating shafts 24b is formed in a longer shape, and the leading end thereof is made to protrude downward from the sprocket 26. A gear 28 for power transmission is firmly fixed to this portion. The gear 28 is meshed with a large-diameter driving gear 30 which is firmly fixed to an output shaft of a circular movement motor 29 extending upward.

Accordingly, when the circular movement motor 29 is started up, the rotating force thereof is transmitted to the timing chain 27 via the gears 28 and 30 and the sprocket 26 firmly fixed to the long rotating shaft 24b. The timing chain 27 rotates circumferentially, by which the four eccentric arms 24 synchronously rotate centering on the respective rotating shafts 24b in the horizontal plane via the other three sprockets 26. Thereby, the carrier holder 20 connected together with the respective eccentric shafts 24a, by extension, the carrier plate 110 held by the holder 20 makes a circular movement without rotating on its own axis in the horizontal plane parallel to the plate 110.

More specifically, the carrier plate 110 circles with such a state that it is eccentric only by a distance L from an axis line e between the upper surface plate 120 and the lower surface plate 130. Urethane type polishing cloths 15 with a degree of hardness (JIS-A) of 80 and a compression rate of 2.5% are pasted to stretch over the respective opposed surfaces of the both surface plates 120 and 130.

This distance L is equal to a distance between the eccentric shaft 24a and the rotating shaft 24b. The circular movements without rotating on its own axis allow all points on the carrier plate 110 to exhibit a small-circular locus equal in dimension (with a radius r). Thereby, the silicon wafer 11 accommodated in a wafer accommodating portion 11a formed in the carrier plate 110 is subjected to simultaneous double side mirror polishing only once such that an amount of polishing is 5 μm on one surface (10 μm on the both surfaces) with the both polishing surface plates 120 and 130 opposite in the rotating direction and by adjusting rotating speeds, polishing pressures, polishing times, and the like of the polishing surface plates 120 and 130.

A polishing liquid free of abrasive grains in which hydroxyethyl cellulose (a water-soluble polymer) of 100 ppm is added to an amine solution (alkaline solution) with a pH of 10.5 is supplied to the both polishing cloths 15 at a predetermined flow rate in this double side polishing.

In this way, provided that the silicon wafer 11 is not subjected to final mirror polishing, the mirror polishing step is simplified and the productivity is improved, that enables a reduction in cost.

Further, since the polishing liquid for mirror polishing in which hydroxyethyl cellulose is added to an amine solution free of abrasive grains is adopted, the hydroxyethyl cellulose receives some of polishing load in polishing, which makes it possible to lower its frictional coefficient. As a result, the silicon wafer is excellent in gate oxide integrity characteristics, and it is possible to considerably reduce the generation of defects such as micro scratches caused by processes, which makes it possible to lower the density of LPD on the surface of an epitaxial film formed thereafter. Moreover, it is possible to reduce the roughness of the surface of the silicon wafer 11, which makes it possible to enhance the quality of the surface roughness of the epitaxial film formed thereafter.

Further, since the hydroxyethyl cellulose is added to the amine solution, the hydroxyethyl cellulose forms a low friction coating between the polishing pads and the carrier plate. Thereby, its frictional coefficient may be efficiently lowered, and an elastic deformation of the carrier plate 110 may be suppressed, which makes it possible to reduce noise generated from the carrier plate 110. Moreover, it is possible to lower the concern that the outer circumference of the silicon wafer 11 is excessively polished due to the fact that the abrasive grains in the polishing liquid easily get dense at the outer circumference of the silicon wafer 11, which may bring about outer circumferential shear droop.

Moreover, diethylenetriamine-pentaacetic acid (DTPA; chelate agent) may be added to an alkaline solution in this polishing liquid. Due to addition of a chelate agent, the chelate agent captures metal ions such as copper ions contained in the polishing liquid to effect complex thereof, which makes it possible to lower a level of metal contamination of the silicon wafers after polishing.

The mirror-polished silicon wafer 11 is subjected to the cleaning step. Here, the respective silicon wafers 11 are subjected to SCl cleaning using an alkaline solution and an acid solution.

The wafer surface after SCl cleaning (each surface is etched by 4 nm by use of an SCl cleaning liquid prepared by mixing at a volume ratio of NH₄OH:H₂O₂:H₂O=1:2:7) was tested by a particle counter (“SP2XP” which is Surf scan SP2 manufactured by KLA-Tencor Corporation). As a result, the number of detected LPD (All the LPD of 130 nm or more were counted) was 140 defects per wafer, which exhibits extremely low LPD density.

Further, the surface roughness of the surface and rear surface of the silicon wafer 11 was an RMS value of 0.277 nm when observing a measuring area region of 10 μm×10 μm by an atomic force microscope, which provided an excellent result. For the observation of the plane roughness (roughness), the “multimode AFM” which is an atomic force microscope manufactured by Veeco Instruments, was adopted. This device is a tapping AFM that vibrates a cantilever at approximately a resonant frequency (with an amplitude of 20 to 100 nm), to observe the unevenness on the wafer surface while making the cantilever intermittently touch the surface of a sample wafer. A force detection mode thereof is dynamic, a resolution is 1 nm, force applied to the sample wafer is 0.1 to 1 nN in the atmosphere, a measuring point is 1 point per wafer (Center), and a roughness indicator (mean heightwise amplitude parameter) is root-mean-square roughness (old RMS).

In addition, for example, in the case where a polishing liquid composed of a KOH solution prepared to have a pH of 10.5 which contains colloidal silica abrasive grains whose mean grain diameter is 40 nm is adopted in place of the polishing liquid free of abrasive grains, the number of detected LPD was 1850 defects per wafer, and the surface roughness of the surface and rear surface of the silicon wafer 11 was an RMS value of 0.458 nm when observing a measuring area region of 10 μm×10 μm by an atomic force microscope.

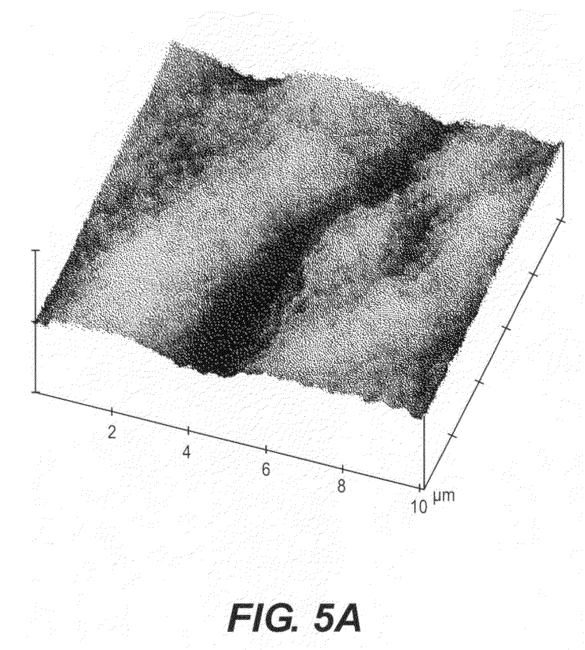

Next, an epitaxial growth step by use of a single wafer vapor phase epitaxial growth apparatus will be described in detail with reference to FIG. 4.

As shown in FIG. 4, a vapor phase epitaxial growth apparatus 60 is that in which a susceptor 61 which is circular in plan view and capable of placing one sheet of a silicon wafer 11 is horizontally disposed on the central portion of a chamber in which heaters are installed at the upper and the lower parts thereof. The susceptor 61 is fabricated by coating a carbon-made base material with SiC.

A recessed counterbore (wafer accommodating portion) which accommodates the silicon wafer 11 in a transversely mounted state (a state in which the surface and rear surface are horizontal) is formed in the inner circumference on the upper surface of the susceptor 61. The counterbore 62 is composed of a circumferential wall 62a, a 6 mm-wide step 62b which is annular in plan view, and a bottom plate (a bottom wall surface of the counterbore) 62c.

A gas supply port which allows a predetermined carrier gas (H₂ gas) and a predetermined source gas (SiHCl₃ gas) to flow in parallel with the wafer surface in the upper space of the chamber is provided in one side portion of the chamber. Further, a gas discharge port is formed in the other side portion of the chamber.

In epitaxial growth, the silicon wafer 11 is transversely mounted so as to set the wafer surface and rear surface horizontally in the counterbore 62. Next, a hydrogen gas is supplied into the chamber to perform hydrogen baking for 60 seconds at a temperature of 1130 degrees with the aim of removing a natural oxide film or particles on the surface of the silicon wafer 11. Thereafter, in place of the hydrogen gas, a carrier gas (H₂ gas) and a source gas (SiHCl₃ gas) are supplied into the chamber. In this state, an epitaxial film 12 is grown on the surface of an RMS value of 0.277 nm when observing a measuring area region of 10 μm×10 μm of the silicon wafer 11 by an atomic force microscope. That is, the carrier gas and the source gas are introduced into a reaction chamber through corresponding gas supply ports. The furnace pressure is kept at 760 Torr, and silicon generated by thermal decomposition or reduction of the source gas is deposited at a reaction speed of 2.5 μm per minute on the silicon wafer 11 heated at a high temperature of 1130 degrees. Thereby, the epitaxial film 12 which is approximately 3.0 μm in thickness of the silicon single crystal is grown on the surface of the silicon wafer 11.

Next, immediately after this epitaxial growth, HCl gas etching is performed in order to reduce the surface roughness of the epitaxial film 12 in the chamber of the vapor phase epitaxial growth apparatus 60. In detail, in place of the growth gas, a hydrogen gas containing HCl gas of 0.5% is supplied into the chamber at a rate of 80 liters per minute while heating the epitaxial silicon wafers 10 to 1130 degrees in the furnace, to perform HCl gas etching for the surface of the epitaxial film 12 only for 0.5 minutes in this state. Accordingly, the surface of the epitaxial film 12 is removed by approximately 30 nm by the HCl etching effect onto the silicon.

In the final cleaning step, the respective epitaxial silicon wafers 10 immediately after an appearance check are cleaned. In detail, the respective epitaxial silicon wafers 10 are subjected to cleaning by use of an alkaline solution and an acid solution.

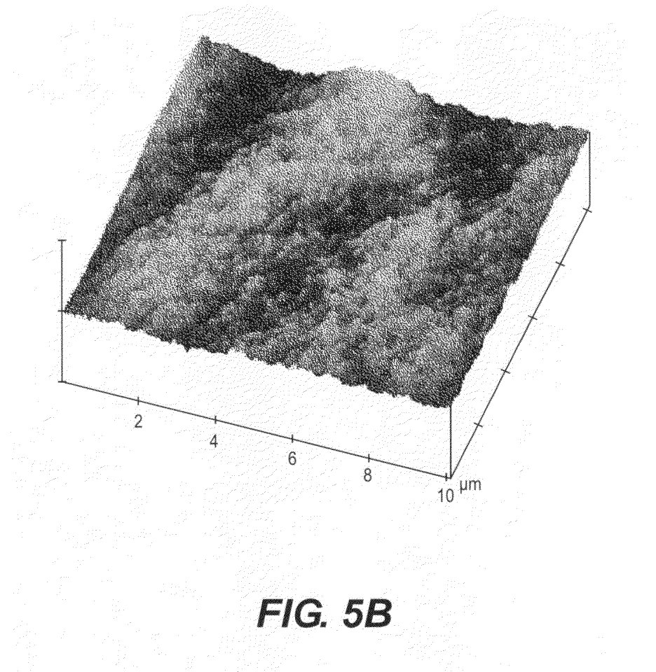

FIG. 5 is a three-dimensional graph showing the plane roughness when observing a measuring area region of 10 μm×10 μm by an atomic force microscope with respect to the surface of the epitaxial silicon wafer in which the epitaxial film 12 is formed on the surface of the silicon wafer 11. FIG. 5A is a result showing the surface roughness of the epitaxial film 12 immediately after the deposition, and FIG. 5B is a result showing the surface roughness of the epitaxial film 12 after the etching onto the surface of the epitaxial film 12 with the HCl gas.

The surface roughness of the epitaxial film 12 immediately after the deposition is an RMS value of 0.100 nm. Meanwhile, the surface roughness after the etching for the surface of the epitaxial film 12 with the HCl gas is an RMS value of 0.091 nm.

### INDUSTRIAL APPLICABILITY

This invention is useful as a method for producing an epitaxial silicon wafer serving as a substrate for manufacturing devices such as bipolar ICs, MOSs, or discrete devices.

1. A method for producing an epitaxial silicon wafer comprising the steps of:
performing vapor-phase growth of an epitaxial film on a surface of a silicon wafer subjected to mirror polishing except for final mirror polishing; and
etching a surface of the epitaxial film with an HCl gas after the vapor-phase growth of the epitaxial film.

2. The method for producing the epitaxial silicon wafer according to claim 1, wherein
a silicon wafer polished with a polishing liquid in which a water-soluble polymer is added to an alkaline solution free of abrasive grains is used as the silicon wafer.

3. The method for producing the epitaxial silicon wafer according to claim 1, wherein
plane roughness of the surface of the silicon wafer is less than or equal to an RMS value of 0.3 nm when measuring a measuring area region of 10 μm×10 μm by an atomic force microscope.

4. The method for producing the epitaxial silicon wafer according to claim 2, wherein
plane roughness of the surface of the silicon wafer is less than or equal to an RMS value of 0.3 nm when measuring a measuring area region of 10 μm×10 μm by an atomic force microscope.

5. The method for producing the epitaxial silicon wafer according to claim 1, wherein
a thickness of the epitaxial film is 1 to 10 μm.

6. The method for producing the epitaxial silicon wafer according to claim 2, wherein
a thickness of the epitaxial film is 1 to 10 μm.

7. The method for producing the epitaxial silicon wafer according to claim 3, wherein
a thickness of the epitaxial film is 1 to 10 μm.

8. The method for producing the epitaxial silicon wafer according to claim 1, wherein,
as conditions of etching for the surface of the epitaxial film with the HCl gas, an HCl gas concentration in an atmosphere gas composed of a mixed gas of an HCl gas and a carrier gas is 0.3 to 3.0%, a heating temperature for the silicon wafer is 1000 to 1180 degrees, and an etching time is 0.3 to 5.0 minutes.

9. The method for producing the epitaxial silicon wafer according to claim 2, wherein,
as conditions of etching for the surface of the epitaxial film with the HCl gas, an HCl gas concentration in an atmosphere gas composed of a mixed gas of an HCl gas and a carrier gas is 0.3 to 3.0%, a heating temperature for the silicon wafer is 1000 to 1180 degrees, and an etching time is 0.3 to 5.0 minutes.

10. The method for producing the epitaxial silicon wafer according to claim 3, wherein,
as conditions of etching for the surface of the epitaxial film with the HCl gas, an HCl gas concentration in an atmosphere gas composed of a mixed gas of an HCl gas and a carrier gas is 0.3 to 3.0%, a heating temperature for the silicon wafer is 1000 to 1180 degrees, and an etching time is 0.3 to 5.0 minutes.

11. The method for producing the epitaxial silicon wafer according to claim 4, wherein,
as conditions of etching for the surface of the epitaxial film with the HCl gas, an HCl gas concentration in an atmosphere gas composed of a mixed gas of an HCl gas and a carrier gas is 0.3 to 3.0%, a heating temperature for the silicon wafer is 1000 to 1180 degrees, and an etching time is 0.3 to 5.0 minutes.

12. The method for producing the epitaxial silicon wafer according to claim 5, wherein,
as conditions of etching for the surface of the epitaxial film with the HCl gas, an HCl gas concentration in an atmosphere gas composed of a mixed gas of an HCl gas and a carrier gas is 0.3 to 3.0%, a heating temperature for the silicon wafer is 1000 to 1180 degrees, and an etching time is 0.3 to 5.0 minutes.
